(19) United States
(12) Patent Application Publication
(10) Pub. No.: US 2015/0322587 A1
(43) Pub. Date: Nov. 12, 2015

(54) SUPER CONFORMAL PLATING

(71) Applicant: APPLIED Materials, Inc., Santa Clara, CA (US)

(72) Inventors: Chris Pabelico, San Jose, CA (US); Roey Shaviv, Palo Alto, CA (US); John L. Klocke, Kalispell, MT (US); Ismail T. Emesh, Sunnyvale, CA (US)

(21) Appl. No.: 14/707,980

(22) Filed: May 8, 2015

Related U.S. Application Data
(63) Continuation-in-part of application No. 14/274,611, filed on May 9, 2014.

(51) Int. Cl. C25D 7/12; H01L 21/288; H01L 21/768

(52) U.S. Cl. CPC C25D 7/123; H01L 21/76879; H01L 21/2885; H01L 21/76873; H01L 21/76841

(57) ABSTRACT

A method for at least partially filling a feature on a workpiece includes electrochemically depositing a metallization layer on a seed layer formed on a workpiece using a plating electrolyte having at least one plating metal ion, a pH range of about 6 to about 13, an organic additive, and first and second metal complexing agents.

### CROSS-REFERENCE TO RELATED APPLICATION

This application is a continuation-in-part (CIP) of U.S. patent application Ser. No. 14/274,611, filed May 9, 2014, the entire disclosure of which is expressly incorporated by reference.

### BACKGROUND

The present disclosure relates to methods for electrochemically depositing a conductive material, for example, a metal, such as copper (Cu), cobalt (Co), nickel (Ni) gold (Au), silver (Ag), tin (Sn), aluminum (Al), and alloys thereof, in features (such as trenches and vias, particularly in Damascene applications) of a microelectronic workpiece.

An integrated circuit is an interconnected ensemble of devices formed within a semiconductor material and within a dielectric material overlying a surface of the semiconductor material. Devices formed within the semiconductor may include metal-oxide-semiconductor transistors, bipolar transistors, diodes, and diffused resistors. Devices formed within the dielectric may include thin film resistors and capacitors. The devices are interconnected by conductor paths formed within the dielectric. Typically, two or more levels of conductor paths, with successive levels separated by a dielectric layer, are employed as interconnections. In current practice, copper and silicon oxide are commonly used for, respectively, the conductor and the low-K dielectric.

The deposits in a copper interconnect typically include a dielectric layer, a barrier layer, a seed layer, copper fill, and a copper cap. Conventional ECD fill using an acid plating electrolyte, particularly in small features, may result in a lower quality interconnect. For example, conventional ECD copper fill may produce voids, particularly in features having a size of less than 30 nm. As one example of a type of void formed using conventional ECD deposition, the opening of the feature may pinch off Other types of voids can also result from using the conventional ECD copper fill process in a small feature. Such voids and other intrinsic properties of a deposit formed using conventional ECD copper fill can increase the resistance of the interconnect, potentially slowing down the electrical performance of the device and deteriorating the reliability of the copper interconnect.

Therefore, there exists a need for an improved, substantially void-free metal fill process for a feature. Such substantially void-free metal fill may be useful in a small feature, for example, a feature having an opening size of less than 30 nm.

### SUMMARY

The summary is provided to introduce a selection of concepts in a simplified form further described below in the Detailed Description. The summary is not intended to identify key features of the claimed subject matter and not to be used as an aid in determining the scope of the claimed subject matter.

In accordance with one embodiment of the present disclosure, a method for at least partially filling a feature on a workpiece is provided. The method includes electrochemically depositing a metallization layer on a seed layer formed on a workpiece using a plating electrolyte having at least one plating metal ion, a pH range of about 6 to about 13, an organic additive, and first and second metal complexing agents.

In accordance with another embodiment of the present disclosure, a method for at least partially filling a feature on a workpiece is provided. The method includes obtaining a workpiece including a feature; and electrochemically depositing a superconformal metallization layer on a seed layer formed on a workpiece using a plating electrolyte having at least one plating metal ion, a pH range of about 6 to about 13, and an accelerator, and further including a first metal complexing agent and a second metal complexing agent.

In any method described herein, the feature diameter may be less than 30 nm.

In any method described herein, the metallization layer may be an electrochemically deposited metal super conformal layer.

In any method described herein, the metallization layer may be annealed.

In any method described herein, the first metal complexing agent may be selected from the group consisting of EDTA, EDA, ammonia, glycine, citrate, tartrate, and urea.

In any method described herein, the second metal complexing agent may be selected from the group consisting of EDTA, EDA, ammonia, glycine, citrate, tartrate, and urea.

In any method described herein, the organic additive may be an accelerator.

In any method described herein, metal for the metallization layer may be selected from the group consisting of copper, cobalt, nickel, gold, silver, tin, aluminum, and alloys thereof.

In any method described herein, the workpiece may further include a barrier layer in the feature between the seed layer and a dielectric surface of the workpiece.

In any method described herein, metal for the seed layer may be selected from the group consisting of copper, cobalt, nickel, gold, silver, manganese, tin, aluminum, ruthenium, and alloys thereof.

In any method described herein, the seed layer may be selected from the group consisting of seed, secondary seed, and a stack film of seed and liner.

### DESCRIPTION OF THE DRAWINGS

The foregoing aspects and many of the attendant advantages of the disclosure will become more readily appreciated by reference to the following detailed description, when taken in conjunction with the accompanying drawings, wherein:

FIG. 1A is a schematic flow diagram depicting a process and an exemplary feature development of an exemplary embodiment of the present disclosure;

FIG. 1B is a comparison schematic flow diagram depicting a process and an exemplary feature development according to a previously developed process;

FIG. 2 is a schematic of a chamfer void in a Damascene feature having a high aspect ratio;

FIG. 3 is a schematic flow diagram depicting a process and an exemplary feature development of another exemplary embodiment of the present disclosure;

FIG. 4A is a schematic flow diagram depicting a process and an exemplary feature development of another exemplary embodiment of the present disclosure;

FIG. 4B is a comparison schematic flow diagram depicting a process and an exemplary feature development according to a previously developed process;

FIGS. 5 and 6 are scanning electron microscopy (SEM) images of a plurality of features, using ECD super conformal copper chemistry in accordance with embodiments of the present disclosure;

FIG. 7 includes a transmission electron microscopy (TEM) image of substantially void-free gap fill for a Damascene feature having a feature size of about 30 nm in accordance with embodiments of the present disclosure;

FIG. 8 is a graphical representation of polarization behavior for various experimental alkaline copper electrolytes; and

FIGS. 9A through 14C are scanning electron microscopy (SEM) images showing feature deposition results for various experimental alkaline copper electrolytes.

### DETAILED DESCRIPTION

Embodiments of the present disclosure are directed to workpieces, such as semiconductor wafers, devices or processing assemblies for processing workpieces, and methods of processing the same. The term workpiece, wafer, or semiconductor wafer means any flat media or article, including semiconductor wafers and other substrates or wafers, glass, mask, and optical or memory media, MEMS substrates, or any other workpiece having micro-electric, micro-mechanical, or microelectro-mechanical devices.

Processes described herein are to be used for metal or metal alloy deposition in features of workpieces, which include trenches and vias. In one embodiment of the present disclosure, the process may be used in small features, for example, features having a feature critical dimension of less than 30 nm. However, the processes described herein are applicable to any feature size. The dimension sizes discussed in the present application may be post-etch feature dimensions at the top opening of the feature. The processes described herein may be applied to various forms of copper, cobalt, nickel, gold, silver, tin, aluminum, and alloy deposition, for example, in Damascene applications. In embodiments of the present disclosure, Damascene features may be selected from the group consisting of features having a size of less than 30 nm.

The descriptive terms “micro-feature workpiece” and “workpiece” as used herein include all structures and layers previously deposited and formed at a given point in the processing, and is not limited to just those structures and layers as depicted in the figures.

Processes described herein may be modified to have an advantageous effect in metal or metal alloy deposition in Damascene features or in high aspect ratio features, for example, vias in through silicon via (TSV) features.

Although generally described as metal deposition in the present application, the term “metal” also contemplates metal alloys and co-deposited material. Such metals, metal alloys, and co-deposited materials may be used to form seed layers or to fully or partially fill the feature. Exemplary copper alloys may include, but are not limited to, copper manganese and copper aluminum. As a non-limiting example, the alloy composition ratio may be in the range of about 0.5% to about 6% secondary alloy metal, as compared to the primary alloy metal (e.g., Cu, Co, Ni, Ag, Au, etc.).

As described above, the conventional fabrication of metal interconnects may include a suitable deposition of a barrier layer on the dielectric material to prevent the diffusion of metal into the dielectric material. Suitable barrier layers, which may include, for example, Ta, Ti, TiN, TaN, Mn, or MnN. Suitable barrier deposition methods may include PVD, ALD and CVD; however, PVD is the most common process for barrier layer deposition. Barrier layers are typically used to isolate copper or copper alloys from dielectric material; however, in the case of other metal interconnects, diffusion may not be a problem and a barrier layer may not be required.

The barrier layer deposition may be followed by an optional seed layer deposition. However, a super conformal metal layer may be deposited directly on the barrier layer, i.e., without a seed layer.

A seed layer may be deposited on the barrier layer. In the case of depositing copper in a feature, there are several exemplary options for the seed layer. First, the seed layer may be a copper seed layer, for example, using a PVD deposition technique. As another non-limiting example, the seed layer may be a copper alloy seed layer, such as copper manganese, copper cobalt, or copper nickel alloys. The seed layer may also be formed by using other deposition techniques, such as CVD or ALD.

Second, the seed layer may be a stack film, for example, a liner layer and a PVD seed layer. A liner layer is a material used in between a barrier and a PVD seed to mitigate discontinuous seed issues and improve adhesion of the PVD seed. Liners are typically noble metals such as ruthenium (Ru), platinum (Pt), palladium (Pd), and osmium (Os), but the list may also include cobalt (Co) and nickel (Ni). Currently, CVD Ru and CVD Co are common liners; however, liner layers may also be formed by using other deposition techniques, such as ALD or PVD.

Third, the seed layer may be a secondary seed layer. A secondary seed layer is similar to a liner layer because it is typically formed from noble metals such as Ru, Pt, Pd, and Os, but the list may also include Co and Ni, and most commonly CVD Ru and CVD Co. (Like seed and liner layers, secondary seed layers may also be formed by using other deposition techniques, such as ALD or PVD.) The difference is the secondary seed layer serves as the seed layer, whereas the liner layer is an intermediate layer between the barrier layer and the PVD Cu seed.

The liner or secondary seed deposit may be thermally treated or annealed at a temperature between about 100° C. to about 500° C. in a forming gas environment (e.g., 3-5% hydrogen in nitrogen or 3-5% hydrogen in helium) to remove any surface oxides and/or surface contaminants, increase the density the secondary seed or liner layer, and/or improve the surface properties of the deposit. The liner or secondary seed deposit may additionally be passivated by the soaking in gaseous nitrogen (N2 gas) or other passivating environments to prevent surface oxidation.

After a seed layer has been deposited (such as one of the non-limiting examples of PVD copper seed, PVD copper seed including CVD Ru liner, or CVD Ru secondary seed, or another deposition metal or metal alloy, layer combination, or deposition technique), the feature may be filled or partially filled with a conductor metal.

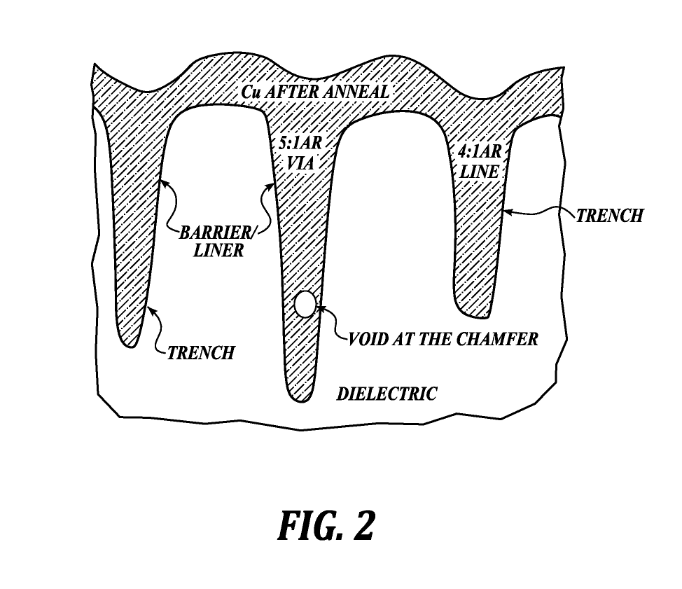

In vias having high aspect ratio, for example, greater than about 5:1, or greater than 7:1, the inventors have discovered the via is susceptible to a void at the chamfer in the dual Damascene process. See, for example, an exemplary chamfer void in FIG. 2. Similarly, high aspect ratio lines with a reentrant profile may exhibit pinch-off at narrow openings or at line ends. In addition, via chains may exhibit pinch-off at narrow opening of the vias.

To solve these problems, embodiments of the present disclosure provide a super conformal deposition process to reduce pinch-off and void formation. In another embodiment of the present disclosure, a post-plating annealing process may further improve void reduction in the feature.

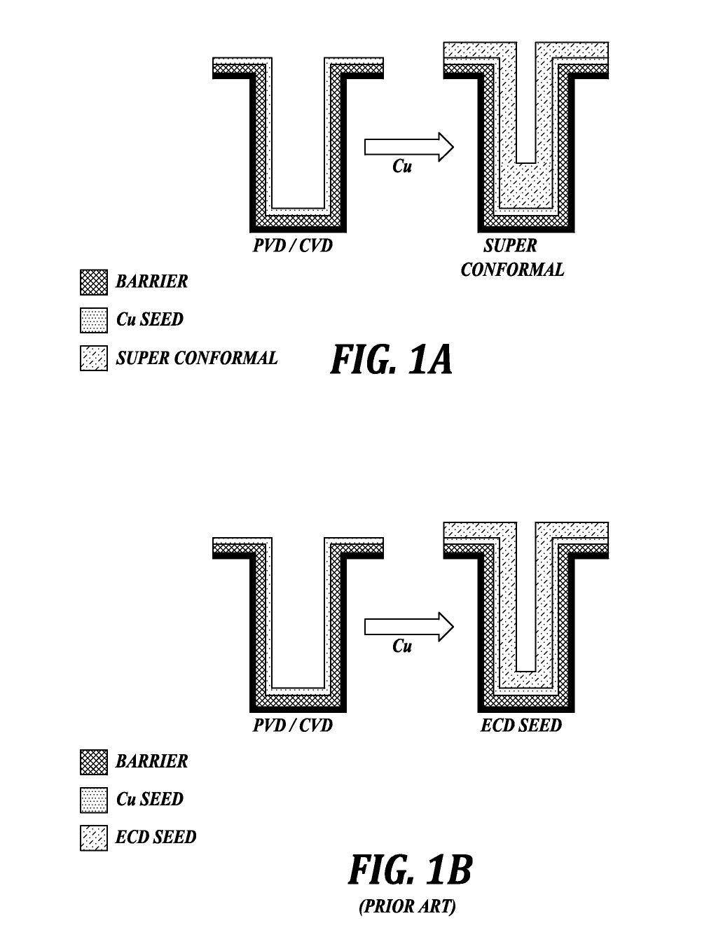

In accordance with one embodiment of the present disclosure, a process for super conformal deposition includes using organic additives (such as accelerators, suppressors, levelers, and any combination thereof) in a pH range of about 6 to about 13, complexed metal deposition process. An alkaline pH and complexed metal deposition process is typically used in an ECD seed process. As described above, an ECD seed layer is typically a conformal layer, for example, conformal ECD seed layer shown in FIG. 1B.

An exemplary ECD copper seed is typically deposited using an alkaline electrolyte including a very dilute copper ethylenediamine (EDA) complex. As other non-limiting examples, the ECD seed layer may be a cobalt or nickel seed layer, deposited using an alkaline electrolyte including a very dilute cobalt or nickel ethylenediamine complex. In one embodiment, the pH of the ECD seed chemistry may be in the range of about 6 to about 12.

An ECD super conformal layer may be deposited using an alkaline electrolyte including a very dilute metal complex, similar to the chemistry used for ECD seed. For example, the ECD super conformal layer may be a copper, cobalt, or nickel layer, deposited using an alkaline electrolyte including a very dilute metal ethylenediamine complex and organic additives. Other complexing agents besides a metal ethylenediamine (EDA) complex may also be used, including, but not limited to ethylenediaminetetraacetic acid (EDTA), ammonia, glycine, citrate, tartrate, and urea.

A suitable pH range for ECD super conformal deposition may be in the range of about 6 to about 13, in one embodiment of the present disclosure about 6 to about 12, and in one embodiment of the present disclosure about 9.3. However, other chemistries may also be used to achieve conformal ECD super conformal deposition.

A suitable bath temperature may be in the range of about 18 degrees Celsius to about 60 degrees Celsius. In one embodiment of the present disclosure, the suitable bath temperature may be in the range of about 30 degrees Celsius to about 60 degrees Celsius. An elevated bath temperature may improve the thermodynamics and adsorption of the additives in the feature.

Organic additives are commonly used in conventional acid ECD fill and cap in a feature, for example, using an acid deposition chemistry. Conventional ECD copper acid chemistry may include, for example, copper sulfate, sulfuric acid, methane sulfonic acid, hydrochloric acid, and organic additives (such as accelerators, suppressors, and levelers). Electrochemical deposition of copper has been found to be a cost effective manner to deposit a copper metallization layer. In addition to being economically viable, the organic additives use in ECD deposition techniques provide for a substantially bottom up (e.g., nonconformal) metal fill mechanically and electrically suitable for interconnect structures.

The organic additives used in conventional ECD fill are generally not used in ECD seed deposition processes because conformal deposition (not bottom-up fill) is usually desirable in an ECD seed deposition process (see FIG. 1B). However, in accordance with embodiments of the present disclosure, the inventors have found using such additives with an ECD seed electrolyte has an advantageous effect of encouraging some bottom-up fill (known as “super conformal” deposition), as opposed to pure conformal deposition, to effectively reduce the aspect ratio in a via. (Compare FIG. 1A showing super conformal ECD deposition with FIG. 1B showing conformal ECD seed deposition.)

Accordingly, the super conformal ECD deposition achieved by the processes described herein may be a hybrid layer having both conformal deposition and bottom-up fill properties, as can be seen in FIG. 1A. The result is a feature with a reduced aspect ratio having the advantageous effect of being less susceptible to void formation at the chamfer.

Referring to FIG. 1A, in accordance with one embodiment of the present disclosure, an ECD super conformal layer is deposited using a chemistry having a pH in the range of about 6 to about 13, a complexing agent, and organic and inorganic additives, such as suppressors, levelers, and accelerators. The result of such chemistry for the ECD super conformal layer is a hybrid seed layer having both bottom-up fill properties to fill the feature.

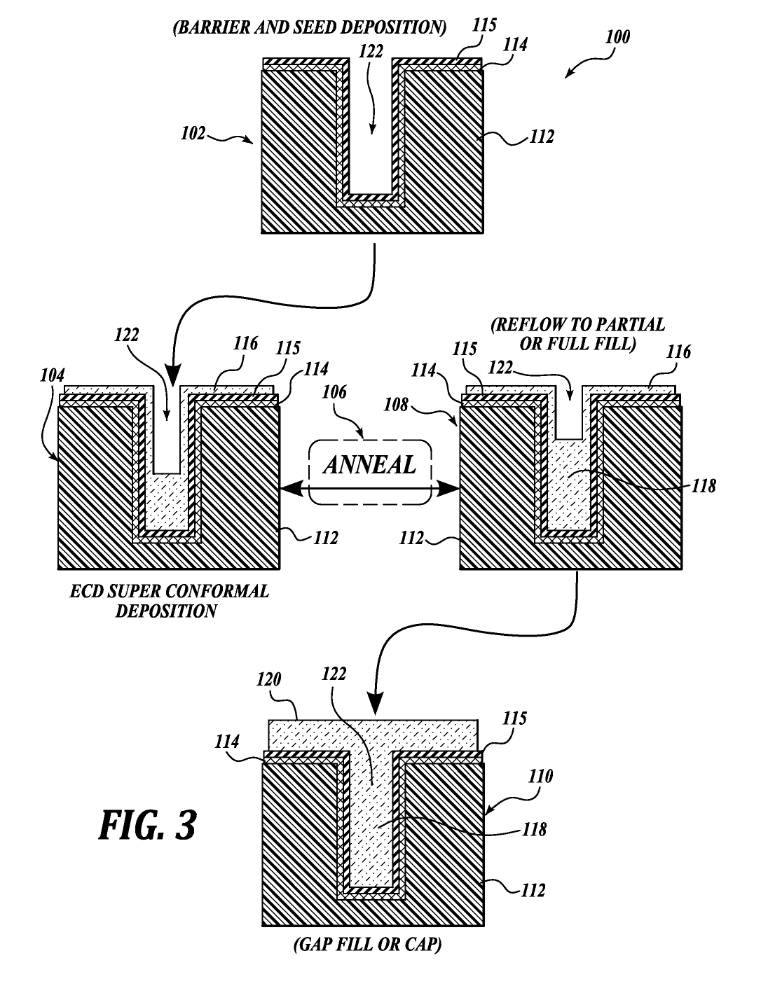

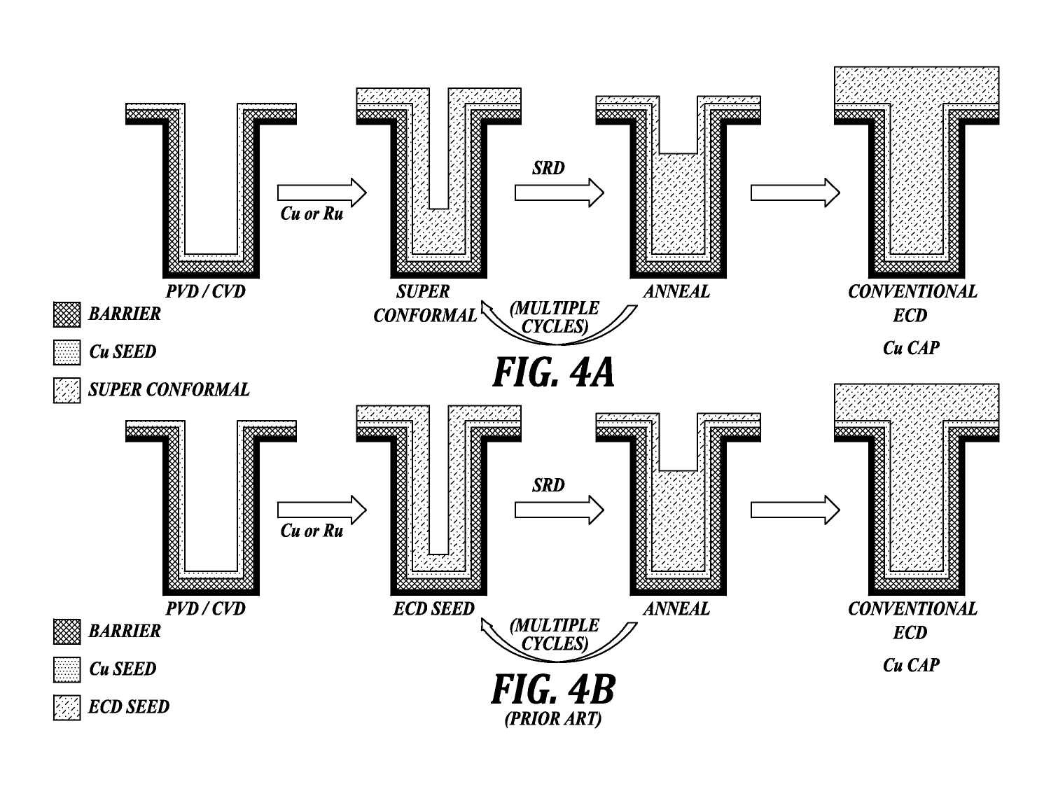

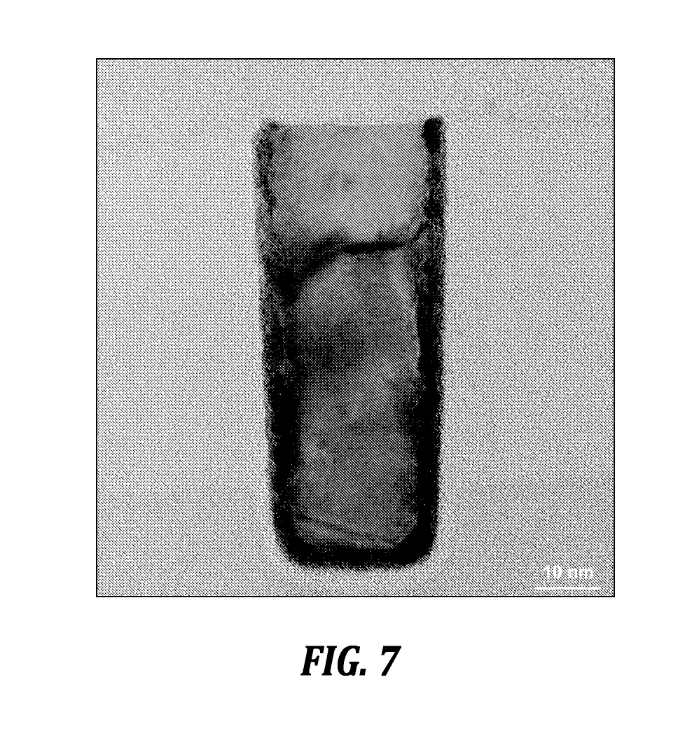

Referring to FIGS. 3 and 4A, the ECD super conformal layer can be thermally treated or annealed to reflow the ECD super conformal layer and at least partially fill the feature. The thermal treatment process provides an advantageous effect of further void reduction. See an image of a representative substantially void-free fill after anneal in a small feature in FIG. 7. Subsequent ECD seed or super conformal layers may be deposited and thermally treated or annealed to further fill the feature. Subsequent layers may be deposited using electrolyte chemistry including organic additives or not including organic additives.

Suitable additives in accordance with embodiments of the present disclosure may include one or more of an accelerator, suppressor, and leveler. In one embodiment of the present disclosure, suitable additives include an accelerator and a leveler.

Suitable accelerators include bis(sodium-sulfopropyl)disulfide (SPS), 3-mercapto-1-propanesulfonic acid (MPS), N,N-dimethyl-dithiocarbamyl propylsulfonic acid sodium salt, 3-(2-benzothiazolyl thio)-1-propanesulfonic acid sodium salt, 3-S-isothiuronium propyl sulfonate (UPS), 8-hydroxy-7-iodo-5-quinolinsulfonic acid, 1-propane sulfonic acid, 3-(ethoxy-thioxomethyl)-thiol sodium salt (OPX), and other suitable accelerators. As a non-limiting example, an accelerator may be added to the ECD super conformal chemistry in a concentration in the range of about 2 to about 40 ppm. As another non-limiting example, an accelerator may be added to the ECD super conformal chemistry in a concentration in the range of about 2 to about 4 ppm.

In addition, potassium iodide (KI) or hydrogen chloride (HCl) may be used to enhance the adsorption of a suppressor to the metal surface. In accordance with embodiments of the present disclosure, KI may be added to the ECD super conformal chemistry in a concentration range of about 1 to about 10 ppm. As a non-limiting example, KI may be added to the ECD super conformal chemistry in a concentration of about 10 ppm. In accordance with embodiments of the present disclosure, HCl may be added to the ECD super conformal chemistry in a concentration range of about 10 to about 50 ppm.

Suitable levelers include commercially available NP5200 suppressor and leveler (DOW Chemicals), polyethyleneimide (PEI), polyethylene glycol (PEG), 1-(2-hydroxyethyl)-2-imidazollidinethione 4-mercaptopyridine; and polymeric amines. In accordance with embodiments of the present disclosure, a leveler may be added to the ECD super conformal chemistry in a concentration range of about 1.0 to about 2.0 ml/L.

In addition to additives, the concentration of copper may be increased from standard concentrations to improve mass transport. In accordance with embodiments of the present disclosure, copper concentration in the ECD super conformal chemistry may be in a concentration range of about 2 mM to about 20 mM.

Process conditions may be controlled to further reduce void formation, such as temperature and pulse testing. For example, a reduced reflow temperature in the range of about 225° C. to about 300° C. may help reduce void formation. In addition, pulse waveform may help improve mass transport into the feature.

After an ECD super conformal layer has been deposited according to the conditions described above, the ECD super conformal layer can be annealed for reflow. Before thermal treatment, the workpiece may be subjected to the spin, rinse, and dry (SRD) process or other cleaning processes. The ECD super conformal layer may then be heated to an adequate anneal temperature to get the layer to reflow, but not too hot for the workpiece or elements on the workpiece to be damaged or degraded. For example, the temperature may be in the range of about 100° C. to about 500° C. for seed reflow in the features. Appropriate thermal treatment or annealing temperatures are in the range of about 100° C. to about 500° C., and may be accomplished with equipment capable of maintaining sustained temperatures in the range of about 200° C. to about 400° C., and at least within the temperature range of about 250° C. to about 350° C.

The thermal treatment or annealing process may be performed using a forming or inert gas, pure hydrogen, or a reducing gas such as ammonia (NH3). During reflow, the shape of the deposition changes, and the metal deposit may pool in the bottom of the feature, as shown in FIGS. 3 and 4A. In addition to reflow during the thermal treatment process, the metal deposit may also grow larger grains and reduce film resistivity. An inert gas may be used to cool the workpiece after heating.

After the thermal treatment process has been completed to either partially or completely fill the feature, a conventional acid chemistry may be used to complete the deposition process for gap fill and cap deposition. Acid chemistry metal deposition is generally used to fill large structures and to maintain proper film thickness needed for subsequent polishing because conventional acid chemistry fill is typically a faster process than ECD seed or super conformal deposition, saving time and reducing processing costs.

As seen in FIGS. 3 and 4A, ECD super conformal deposition and reflow may be repeated to ensure complete filling of the feature. Processes described herein may include one or more ECD super conformal deposition, cleaning (such as SRD), and thermal treatment cycles.

### Example 1

### Conventional Additive System

Using a dilute copper ECD seed electrolyte of 0.002 M copper, the inventors found the conventional additive system (accelerator, suppressor, and leveler) combined with the ECD seed electrolyte was producing improved gap fill results. Therefore, responses from individual additives were further investigated.

### Example 2

### Modified Additive System

After investigation of the responses from the individual additives, a mixture of an accelerator (SPS or OPX) and a leveler (NP5200) was found to provide some advantages in gap fill results in a dilute copper ECD seed electrolyte of 0.002 M copper. The accelerator was found to provide accelerating effects and the leveler was found to provide suppressing effects in the ECD seed electrolyte.

The additive combination of accelerator and leveler produced the signal of bottom-up fill. However, some of the larger structures did not fill. ECD seed electrolyte was operating near a mass transport limited regime.

### Example 3

### Pulse Testing

To address the problem of mass transport discussed in EXAMPLE 2 above, waveform pulse testing was investigated. A standard pulse of 10 ms “on” followed by 10 ms “off” was applied for a chemistry including 0.002 M copper, 2 ppm accelerator, and 1.0 ml/1 leveler, and having a pH of 9.3. Comparatively, an increased pulse of 10 ms “on” followed by 40 ms “off” was applied for the same chemistry. The diffusion of copper into the structure of roughly 40 nm by 160 nm was approximated to take about 0.05 ms (with a diffusion coefficient for copper of 5.3×10[−6] cm2/s and a concentration of copper of 0.002 M). The change in pulse waveform did not significantly affect bottom-up fill.

### Example 4

### Mass Transport

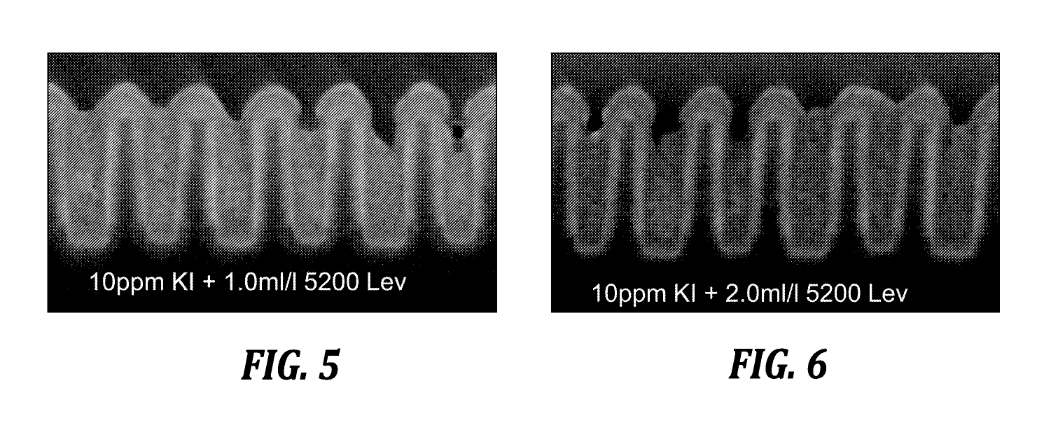

To address the problem of mass transport discussed in EXAMPLE 2 above, copper concentration will be increased to 0.1 M. Improved bottom-up fill results will be achieved using increased copper concentration in combination with additive concentrations of (1) 2 ppm accelerator and 1.0 ml/L leveler and (2) 2 ppm accelerator and 2.0 ml/L leveler, as shown in the predicted SEM images in FIGS. 5 and 6.

In accordance with another embodiment of the present disclosure, a process for super conformal deposition includes a pH range of about 6 to about 13 and a complexed metal deposition process using at least two complexing agents and an organic additive, such as an accelerator described above. In some applications of an ECD seed process, only one complexing agent is used. However, the inventors have found two complexing agents can have a synergistic effect providing advantageous results.

As non-limiting examples, the ECD super conformal layer may be a copper, cobalt, or nickel layer, deposited using an alkaline electrolyte including, as a non-limiting example, a metal ethylenediamine (EDA) complex and a metal ethylenediaminetetraacetic acid (EDTA) complex. As another non-limiting example, another combination of complexing agents includes EDTA and Tartrate.

Other complexing agent combinations besides EDA and EDTA and EDTA and Tartrate may also be used. In one embodiment of the present disclosure, each complexing agent in the pair of complexing agent has a unique property. For example, one complex may be very stable (e.g., EDTA) and the other may be less stable (e.g., EDA or Tartrate).

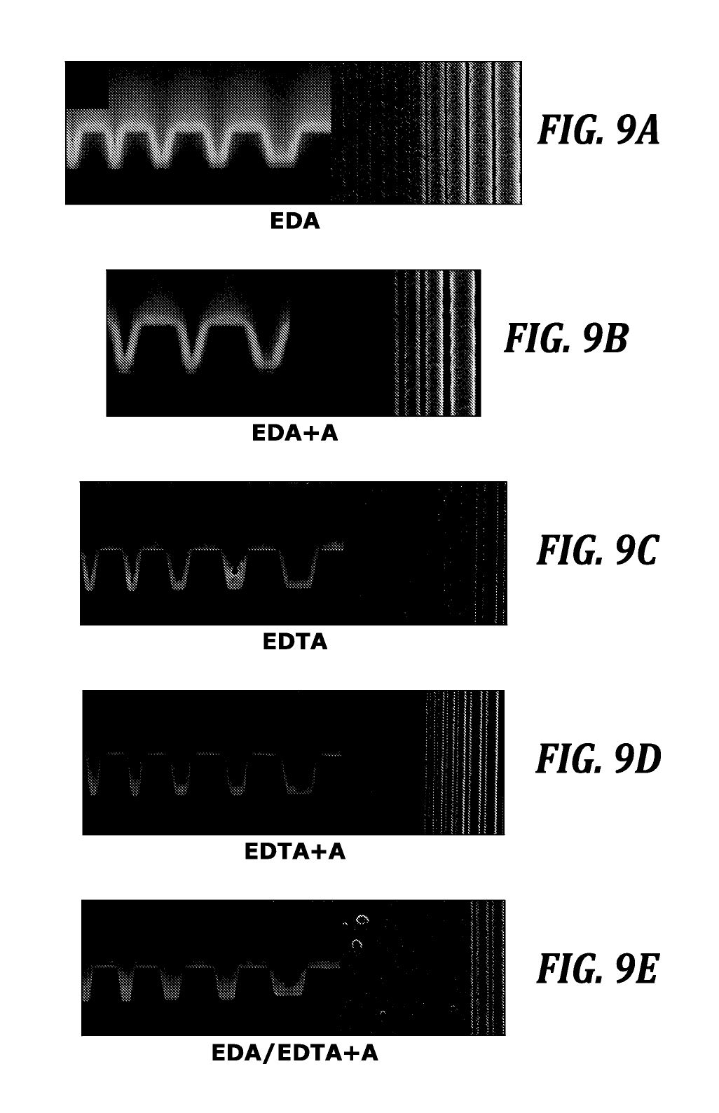

An exemplary ECD copper seed may be deposited using an alkaline electrolyte including a combined Cu(EDA)₂/Cu(EDTA) complex. When CuEDA and CuEDTA complexes are combined, the inventors have observed strong polarization for CuEDTA provides a suppressing effect in small features. The combination of CuEDA and CuEDTA then provides a source for Cu to fill the features and to promote plating. The result is super conformal deposition as can be seen in the FIGS. 9A-9E.

As other non-limiting examples, the ECD metal layer may be a cobalt or nickel layer deposited using an alkaline electrolyte including a very dilute Co(EDA)₂/Co(EDTA) or Ni(EDA)₂/Ni(EDTA) complex.

A suitable pH range for ECD super conformal deposition may be in the range of about 6 to about 13, in one embodiment of the present disclosure about 6 to about 12, and in one embodiment of the present disclosure about 9.3. However, other electrolytes may also be used to achieve conformal ECD super conformal deposition.

In one embodiment of the present disclosure, the ratio of the two complexes may be any suitable ratio and may vary between x% and (100−x)%. The mixture may have excess of either complexing agent to ensure stable stoichiometry of the desired metal complex moiety. In one embodiment of the present disclosure, the ratio of the less stable complexing agent to the more stable complexing agent is 1 or less.

The potential and kinetics of the cupric ion reduction reaction in an aqueous solution depends on the formation constant of the cupric-ligand complex. The equilibrium potential E_{Cu} for cupric ion reduction can be expressed by the Nerst equation, as follows.

E=E₀−(0.0502/2)LOG(STABILITY CONSTANT)

The higher the stability constant of the complex, the more negative the reduction potential. In one embodiment of the present disclosure, the more stable Cu complex (such as EDTA) may enhance the suppression of Cu plating on the field, while the less stable Cu complex acts as a source of Cu ions for super conformal plating in the feature (having bottom up fill, as opposed to conformal fill).

### Example 5

### Polarization Behavior for Cu(EDA)₂/Cu(EDTA) Complex

Cu was plated using ECD Seed electrolytes including various Cu complexes: (1) Cu(EDA)₂ only; (2) Cu(EDTA) only; and (3) combined Cu(EDA)₂/Cu(EDTA) Each electrolyte had a pH of 9.3, a Cu concentration of 10 mM, and plating was at a current density of 1 mA/cm². In addition, Cu was plated using the same three ECD Seed electrolytes, each with Accelerator A added.

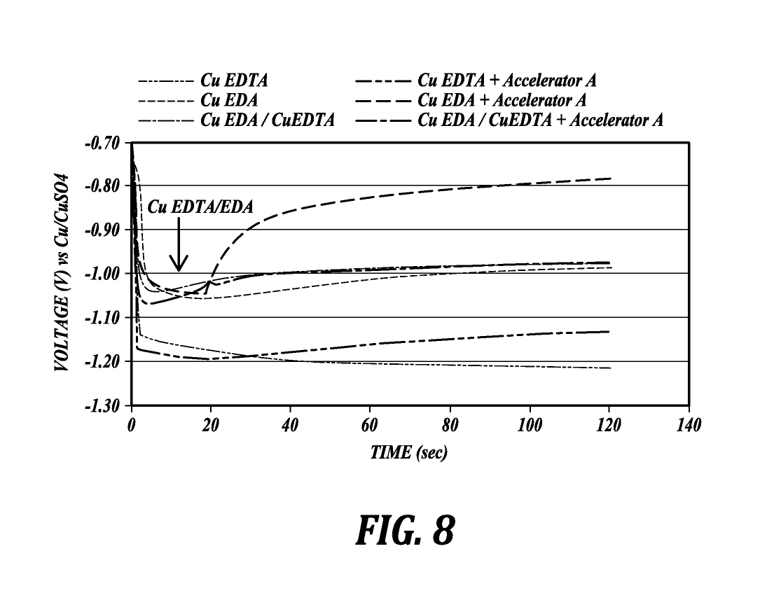

The results show strong polarization for Cu(EDTA). In addition, the EDTA/EDA Cu complex mixture shows about 200 mV depolarization. Compare graphical data in FIG. 8.

### Example 6

### Cu(EDA)₂/Cu(EDTA) Complex with Accelerator A

Cu was plated using ECD Seed electrolytes including various Cu complexes: (1) Cu(EDA)₂ only (FIG. 9A); (2) Cu(EDA)₂ plus Accelerator A (FIG. 9B); (3) Cu(EDTA) only (FIG. 9C); (4) Cu(EDTA) plus Accelerator A (FIG. 9D); and (5) combined Cu(EDA)₂/Cu(EDTA) plus Accelerator A (FIG. 9E). Each electrolyte had a pH of 9.3, a Cu concentration of 10 mM, and plating was at a current density of 1 mA/cm². For the mixed complex, the ratio was 1:1. The Cu to ligand ratio was 1:2 in all complexes.

The results show conformal deposition with single complexes, with or without Accelerator A. The results show super conformal deposition for the mixed complex sample (5) with Accelerator A in 5× (50-60 nm) or larger features. Compare super conformal deposition in SEM image in FIG. 9E with conformal deposition in other SEM images in FIGS. 9A to 9D.

### Example 7

### Cu(EDA)₂/Cu(EDTA) Complex with Cu Concentration and Current Variations

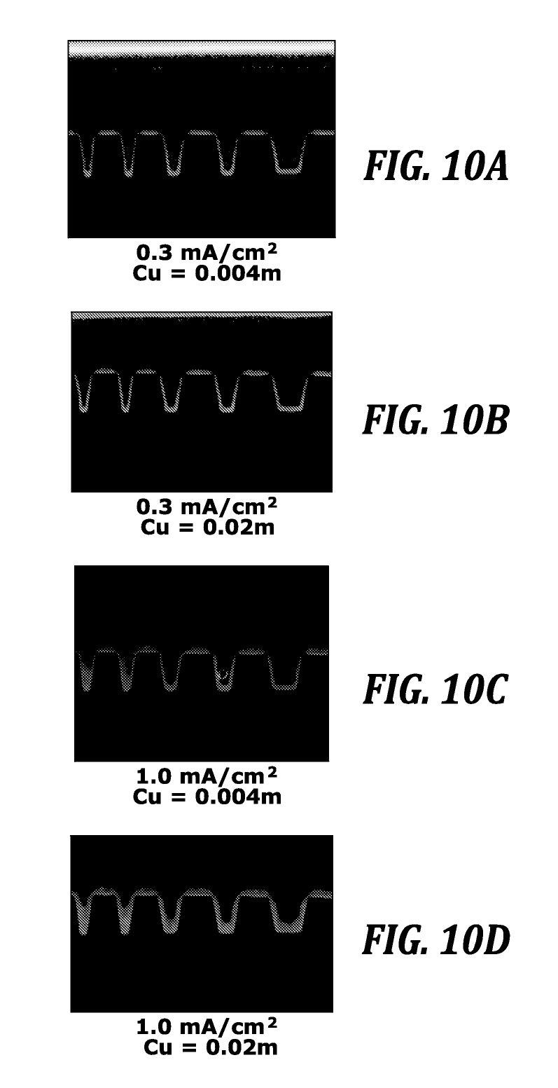

Cu was plated using ECD Seed electrolytes including various Cu complexes: (1) combined Cu(EDA)₂/Cu(EDTA) plus Accelerator A concentration of 0.6 ml/l, Cu concentration of 4 mM, and current density of 0.3 mA/cm² (FIG. 10A); (2) combined Cu(EDA)₂/Cu(EDTA) plus Accelerator A concentration of 0.6 ml/l, Cu concentration of 4 mM, and current density of 1.0 mA/cm² (FIG. 10B); (3) combined Cu(EDA)₂/Cu(EDTA) plus Accelerator A concentration of 0.6 ml/l, Cu concentration of 20 mM, and current density of 0.3 mA/cm² (FIG. 10C); and (4) combined Cu(EDA)₂/Cu(EDTA) plus Accelerator A concentration of 0.6 ml/l, Cu concentration of 20 mM, and current density of 1.0 mA/cm² (FIG. 10D). Each electrolyte had a pH of 9.3. The mixed complex ratio was 1:1. The Cu to ligand ratio was 1:2 in all complexes.

The results show super conformal deposition for the mixed complex with Accelerator A sample (4) having a Cu concentration of 20 mM and current density of 1.0 mA/cm² in 5× (50-60 nm) or larger features. Compare super conformal deposition in SEM image in FIG. 10D with conformal deposition in other SEM images in FIGS. 10A-10C.

### Example 8

### Conformal Plating

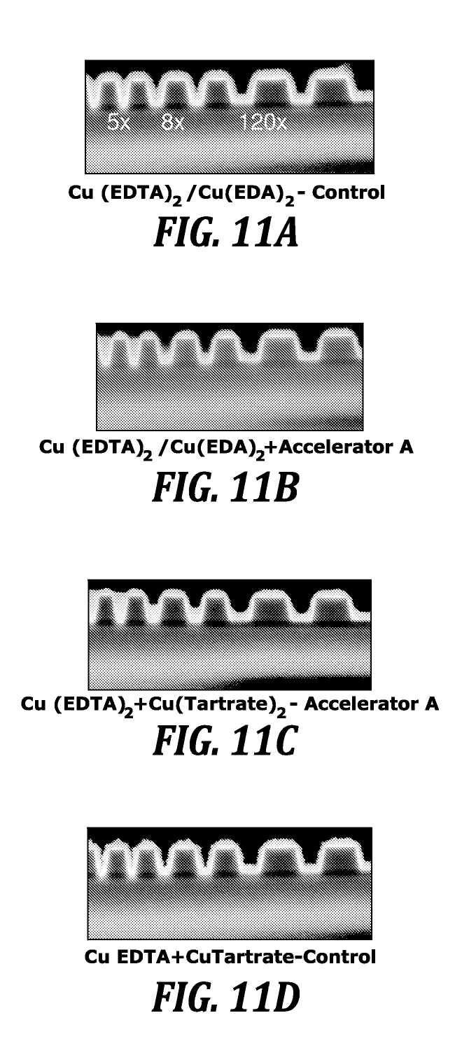

Cu was plated using ECD Seed electrolytes including various Cu complexes: (1) combined Cu(EDA)₂/Cu(EDTA) plus Accelerator A concentration of 0.6 ml/l, Cu concentration of 4 mM, and current density of 0.3 mA/cm² (FIG. 11A); (2) combined Cu(EDA)₂/Cu(EDTA) plus Accelerator A concentration of 0.6 ml/l, Cu concentration of 4 mM, and current density of 1.0 mA/cm² (FIG. 11B); (3) combined Cu(EDA)₂/Cu(EDTA) plus Accelerator A concentration of 0.6 ml/l, Cu concentration of 20 mM, and current density of 0.3 mA/cm² (FIG. 11C); and (4) combined Cu(EDA)₂/Cu(EDTA) plus Accelerator A concentration of 0.6 ml/l, Cu concentration of 20 mM, and current density of 1.0 mA/cm² (FIG. 11D). Each electrolyte had a pH of 9.3. The mixed complex ratio was 1:1. The Cu to ligand ratio was 1:2 in all complexes.

The results show conformal plating in the absence of an accelerator, and super conformal deposition for a mixed complex electrolyte including Accelerator A. Compare super conformal deposition in SEM image in FIGS. 11B and 11C with conformal deposition in other SEM images in FIGS. 11A and 11D.

### Example 9

### Concentration Impact on Super ECD Results

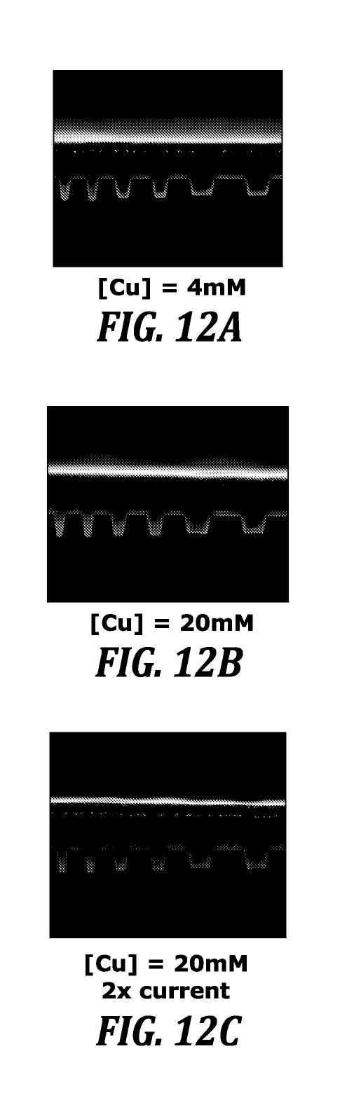

Cu was plated using ECD Seed electrolyte including two Cu complexes: Cu(EDA)₂ and Cu(EDTA), the electrolyte having a pH of 9.3 and current density of 1 mA/cm². The ligand to Cu ratio in the Cu(EDA)₂ and the Cu(EDTA) complex was at 2:1. The Cu(EDA)₂ to Cu(EDTA) complex ratio was 1. The Cu concentration was varied from 4 mM to 20 mM (see respective FIGS. 12A and 12B). In addition, for a second 20 mM sample, current density was increased by 2× (see FIG. 12C).

The results show increasing Cu concentration increases the plating efficiency. Compare super conformal deposition in TEM image in FIG. 12B with conformal deposition in TEM image in FIG. 12A. Also a 2× increase in current density made insignificant changes in plating. Compare super conformal deposition in SEM image in FIG. 12B with super conformal deposition in SEM images in FIG. 12C.

### Example 10

### Complex Ratio Impact on Super ECD Results

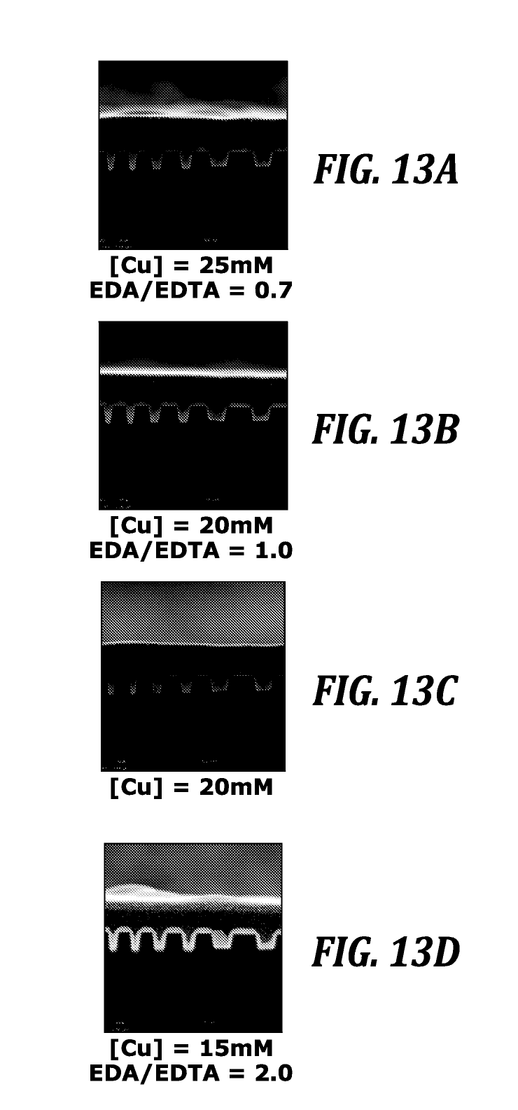

Cu was plated using ECD Seed electrolyte including two Cu complexes: Cu(EDA)₂ and Cu(EDTA), the electrolyte having a pH of 9.3 and current density of 1 mA/cm². The ligand to Cu ratio in both the Cu(EDA)₂ and the Cu(EDTA) complex was at 2:1. The Cu(EDA)₂-Cu concentration was 10 mM. The Cu(EDA)₂ to Cu(EDTA) complex ratio was increased from 0.7 (FIG. 13A), to 1.0 (FIG. 13B), to 2.0 (FIG. 13D). Only Cu(EDTA) is used in FIG. 13C.

The results show increasing the Cu(EDA)₂ to Cu(EDTA) complex ratio reduces super conformal plating in the trenches. Compare FIGS. 13A, 13B and 13D. Therefore, an advantageous Cu(EDA)₂ to Cu(EDTA) ratio is 1 or less than 1.

### Example 11

### Excess EDTA Concentration Impact on Super ECD Results

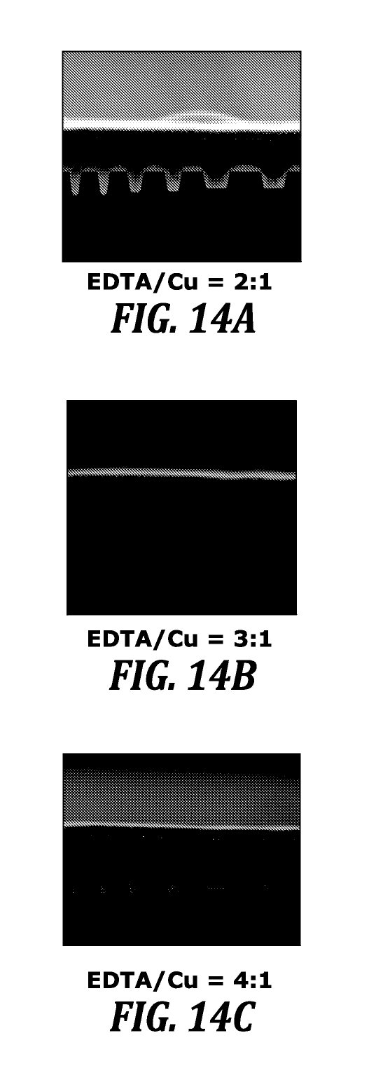

Cu was plated using ECD Seed electrolyte including two Cu complexes: Cu(EDA)₂ and Cu(EDTA), the electrolyte having a pH of 9.3 and current density of 1 mA/cm². The ratio Cu(EDA)₂ to Cu(EDTA) was 1. The ligand to Cu ratio in the Cu(EDTA) complex was varied from 2:1 (FIG. 14A) to 3:1 (FIG. 14B) to 4:1 (FIG. 14C).

The results show increasing the ligand to Cu ratio in the Cu(EDTA) complex has an insignificant impact on the plating results. Compare FIGS. 14A to 14C.

While illustrative embodiments have been illustrated and described, various changes can be made therein without departing from the spirit and scope of the disclosure.

The embodiments of the invention in which an exclusive property or privilege is claimed are defined as follows:

1. A method for at least partially filling a feature on a workpiece, the method comprising:
electrochemically depositing a metallization layer on a seed layer formed on a workpiece using a plating electrolyte having at least one plating metal ion, a pH range of about 6 to about 13, an organic additive, and first and second metal complexing agents.

2. The method of claim 1, wherein the feature diameter is less than 30 nm.

3. The method of claim 1, wherein the metallization layer is an electrochemically deposited metal super conformal layer.

4. The method of claim 1, wherein the metallization layer is annealed.

5. The method of claim 1, wherein the first metal complexing agent is selected from the group consisting of EDTA, EDA, ammonia, glycine, citrate, tartrate, and urea.

6. The method of claim 1, wherein the second metal complexing agent is selected from the group consisting of EDTA, EDA, ammonia, glycine, citrate, tartrate, and urea.

7. The method of claim 1, wherein the organic additive is an accelerator.

8. The method of claim 1, wherein metal for the metallization layer is selected from the group consisting of copper, cobalt, nickel, gold, silver, tin, aluminum, and alloys thereof.

9. The method of claim 1, wherein the workpiece further includes a barrier layer in the feature between the seed layer and a dielectric surface of the workpiece.

10. The method of claim 1, wherein metal for the seed layer is selected from the group consisting of copper, cobalt, nickel, gold, silver, manganese, tin, aluminum, ruthenium, and alloys thereof.

11. The method of claim 1, wherein the seed layer is selected from the group consisting of seed, secondary seed, and a stack film of seed and liner.

12. A method for at least partially filling a feature on a workpiece, the method comprising:
(a) obtaining a workpiece including a feature; and
(b) electrochemically depositing a superconformal metallization layer on a seed layer formed on a workpiece using a plating electrolyte having at least one plating metal ion, a pH range of about 6 to about 13, and an accelerator, and further including a first metal complexing agent and a second metal complexing agent.
